(19) United States
(12) Patent Application Publication
(10) Pub. No.: US 2026/0282278 A1
(43) Pub. Date: Sep. 17, 2026

(54) RACK ENABLING CONFIGURABLE DOMAIN ARCHITECTURE

(71) Applicant: Nvidia Corporation, Santa Clara, CA (US)

(72) Inventors: Elad MENTOVICH, Tel Aviv (IL); John NORTON, Houston, TX (US); Sam HAND, Sugar Land, TX (US); Ryan ALBRIGHT, Beaverton, OR (US); David HERRING, Apex, NC (US)

(21) Appl. No.: 19/080,022

(22) Filed: Mar. 14, 2025

(51) Int. Cl. H05K 7/20; H05K 7/14

(52) U.S. Cl. CPC H05K 7/20272; H05K 7/1489; H05K 7/1492; H05K 7/20781

(57) ABSTRACT

A server rack is provided that includes a plurality of tray support structures each configured to support a tray. Each support structure accommodates a selected one of air cooling or liquid cooling of the tray supported by the support structure.

### BACKGROUND

Datacenters often include a plurality of racks that host trays of computing resources (e.g., graphical processing units (GPUs), central processing units (CPUs), data processing units (DPUs), and/or the like) and resource orchestrators. Different trays may have different requirements regarding cooling, power supply, connection with other trays, and/or the like. For example, the connections between the trays in various racks defines the architecture of the data center. Conventional racks may require different trays with different cooling, power supply, and/or other requirements to be mounted within different racks. However, when trays that are assigned to the same L1 domain of the datacenter are hosted by different racks, communication latency and/or signal degradation across long distances across the datacenter may reduce the efficiency and reliability of the datacenter. Therefore, there is a need in the art for techniques and server racks enabling mounting trays with various requirements within the same server rack.

### GENERAL DESCRIPTION

Datacenters often include a plurality of server racks having respective pluralities of trays mounted therein. The trays may include carious components that communicate with one another via a fast and robust communication infrastructure. For example, optical interconnects may enable communication between various trays and/or server racks. In at least one example embodiment, the optical interconnect is part of a datacenter that corresponds to a collection of network devices, such as network switches (e.g., Ethernet switches, IP routers, multiservice platforms, various transmission network elements, legacy communication equipment, or in any other suitable communication system) connected with a collection of servers or compute nodes. A switch fabric serves to transfer the data between the switch ports. A switch fabric comprises one or more interconnect circuits, which may be arranged in various switch fabric architectures, e.g., m*m crossbar, Banyan, Benes, Omega, Clos, multi-plane, STS, TST, shared memory, buffered crossbar, any other suitable blocking or non-blocking architecture, or any applicable mixed architecture thereof. A switch fabric is realized in typical embodiments by hardware, which may comprise Field-Programmable Gate Arrays (FPGAs) and/or Application-Specific Integrated Circuits (ASICs), and in some implementations also bus interconnects. The datacenter may adhere to a networking topology (e.g., a hierarchal networking topology), such as a fat tree topology, a Slim Fly topology, a Dragonfly topology, and/or the like. The datacenter routes traffic amongst the network switches and servers therein, and at least one layer of the topology in the datacenter is coupled to the communication network to allow networking traffic to flow between the datacenter and the network device(s).

In some embodiments, optical interconnects include transceivers used to connect network-connected devices (e.g., remote client switches, network adapters such as Network Interface controllers (NICs) and Host Channel Adapters (HCAs), Smart-NICs (NICs having embedded CPUs), network-enabled Graphics Processing Units (GPUs), and the like). The terms “network-connected device” and “network device” are used interchangeably herein. In certain embodiments, an optical interconnect includes a substrate, one or more optical waveguides, one or more first micro-lenses, one or more second micro-lenses, and first and second mechanical fixtures.

A “node” as described herein may refer to a network switch to which a plurality of computer processing units (CPUs), graphical processing units (GPUs), data processing units (DPUs), or memory media are connected in an arbitrary number. The network switch may communicate with other network switches of the same kind to which the same processor and memory units may be connected. However, in other implementations, “node” may also refer to a processor which may be responsible for communication with all other nodes in the network or subnetwork.

An “optical fiber” as described herein can refer to a single optical fiber (e.g., including a core and a cladding) to provide unidirectional optical communication, can refer to a bidirectional pair of optical fibers (e.g., each including a core and a cladding) to provide both transmit and receive communications in an optical network, or can refer to a multi-core fiber, such that a single cladding could encapsulate a plurality of single-mode cores. Optical fibers can extend contiguously and uninterrupted between node or send/receive pairs (e.g., via pass-through connections) or include two or more fibers connected via fiber-to-fiber connections such that the fibers function or perform as a single fiber.

Silicon Photonics (SiP) is a technology that enables optical systems to be manufactured using silicon processes with silicon as the optical medium. Various optical components, such as interconnects and signal processing components, may be fabricated and integrated in a single SiP device. Some SiP devices are fabricated on a silica substrate or over a silica layer on a silicon substrate, a technology that is often referred to as Silicon on Insulator (SOI). In certain optical systems, a SiP device is attached to an external device to facilitate optical communications. However, it is generally difficult to accurately align light signals on the SiP with an external device that receives the light.

In certain optical systems, a SiP device is attached to an external device to facilitate optical communications. For example, the system includes one or more waveguides that carry light signals to and/or from optical chips. Examples of optical chips that can be included on the device include, but are not limited to, one or more components selected from a group consisting of facets through which light signals can enter and/or exit a waveguide, entry/exit ports through which light signals can enter and/or exit a waveguide from above or below the device, multiplexers for combining multiple light signals onto a single waveguide, demultiplexers for separating multiple light signals such that different light signals are received on different waveguides, optical couplers, optical switches, lasers that act as a source of a light signal, amplifiers for amplifying the intensity of a light signal, attenuators for attenuating the intensity of a light signal, modulators for modulating a signal onto a light signal, modulators that convert a light signal to an electrical signal, and vias that provide an optical pathway for a light signal traveling through the device. Additionally, the device can optionally, include electrical components. For instance, the device can include electrical connections for applying a potential or current to a waveguide, controlling active optical components, such as modulators, for example, and/or for controlling other components on the optical device.

In various embodiments, server racks are provided that are configured to receive and/or accommodate a variety of trays. For example, some trays in a server rack may be configured to be cooled via liquid cooling and some trays in a server rack may comprise integrated fans and be configured for air cooling. The server rack may be configured such that any arrangement of liquid cooled and/or air-cooled trays may be mounted therein. In certain embodiments, the server rack includes a chassis, flanges, and rails that are in accordance with the Electronic Industries Alliance (EIA) standards. The server rack may also include a cable cartridge in accordance with EIA standards and/or a busbar that is Open Rack Version 3 (ORV3) standards compliant.

According to an aspect of the present disclosure, a server rack is provided. In an example embodiment, the server rack includes a plurality of tray support structures each configured to support a tray. Each support structure accommodates a selected one of air or liquid cooling of the tray supported by the support structure. The rack may be provided with an integrated busbar and liquid cooling manifold.

In an example embodiment, the server rack further includes chassis and rails that are Electronic Industries Alliance (EIA) standards compliant, wherein the chassis comprises the plurality of tray support structures; and a busbar that is Open Rack Version 3 (ORV3) standards compliant.

In an example embodiment, the server rack further includes a liquid cooling manifold comprising a plurality of pluggable liquid cooling connectors that each correspond to a respective support structure.

In an example embodiment, each pluggable liquid cooling connector of the plurality of liquid cooling connectors is configured to enable a tray to selectively be placed into fluid communication with the liquid cooling manifold and to fluidly seal an access point to the liquid cooling manifold when a tray is not selectively placed into fluid communication with the liquid cooling manifold via the pluggable liquid cooling connector.

In an example embodiment, each pluggable liquid cooling connector of the plurality of liquid cooling connectors comprises an access point configured for providing fluid communication access with the liquid cooling manifold.

In an example embodiment, each pluggable liquid cooling connector of the plurality of liquid cooling connectors comprises a sealing component configured to fluidly seal the access point when the access point is not being used to selectively place a tray into fluid communication with the liquid cooling manifold.

In an example embodiment, the sealing component is further configured to at least in part seal a fluid connection between the tray and the access point when the access point is being used to selectively place a tray into fluid communication with the liquid cooling manifold.

In an example embodiment, the server rack is configured to accommodate trays comprising tray integrated fans.

In an example embodiment, the server rack further includes a cable cartridge comprising a plurality of cable connectors that each correspond to a respective support structure.

In an example embodiment, the cable cartridge is configured to define one or more L1 domains within the server rack. The cable cartridge is configured to enable independent powering of components at the tray or L1 level within the rack.

According to another aspect of the present disclosure, a plurality of vertical structural members extending from a bottom of the server rack to a top of the server rack and defining a front side, a back side, and two lateral sides of the server rack; a busbar disposed on the back side of the server rack and extending at least part way between the top of the server rack and the bottom of the server rack; a liquid cooling manifold extending at least part way between the top of the server rack and the bottom of the server rack and comprising pluggable liquid cooling connectors disposed at a plurality of tray locations; and a cable cartridge mounted on the back side of the server rack and comprising cable connectors at disposed at the plurality of tray locations. The server rack is configured to receive respective trays at respective tray locations of the plurality of tray locations such that the respective trays receive electrical power via the busbar, optionally received liquid coolant via the liquid cooling manifold, and interconnectivity between the respective trays is controlled via the cable cartridge.

In an example embodiment, the server rack further includes a chassis comprising a plurality of tray support structures that are configured to define the plurality of tray locations.

In an example embodiment, the server rack further includes rails that are Electronic Industries Alliance (EIA) standards compliant, the chassis is EIA compliant, and the busbar is Open Rack Version 3 (ORV3) standards compliant.

In an example embodiment, each pluggable liquid cooling connector of the plurality of liquid cooling connectors is configured to enable a tray to selectively be placed into fluid communication with the liquid cooling manifold and to fluidly seal an access point to the liquid cooling manifold when a tray is not selectively placed into fluid communication with the liquid cooling manifold via the pluggable liquid cooling connector.

In an example embodiment, each pluggable liquid cooling connector of the plurality of liquid cooling connectors comprises an access point configured for providing fluid communication access with the liquid cooling manifold.

In an example embodiment, each pluggable liquid cooling connector of the plurality of liquid cooling connectors comprises a sealing component configured to fluidly seal the access point when the access point is not being used to selectively place a tray into fluid communication with the liquid cooling manifold.

In an example embodiment, the sealing component is further configured to at least in part seal a fluid connection between the tray and the access point when the access point is being used to selectively place a tray into fluid communication with the liquid cooling manifold.

In an example embodiment, the server rack is configured to accommodate trays comprising tray integrated fans.

In an example embodiment, the cable cartridge is configured to define one or more L1 domains within the server rack.

In an example embodiment, the cable cartridge is configured to define a topology of at least a portion of a computing network housed by the server rack.

### BRIEF DESCRIPTION OF THE SEVERAL VIEWS OF THE DRAWINGS

Reference will now be made to the accompanying drawings, which are not necessarily drawn to scale, and wherein:

FIG. 1 provides a front perspective view of an example server rack having a tray mounted at a tray position, in accordance with certain embodiments;

FIG. 2 provides a front perspective view of an example server rack, in accordance with certain embodiments;

FIG. 3 provides a back perspective view of an example server rack, in accordance with certain embodiments;

FIG. 4 provides a back perspective view of an example server rack, in accordance with certain embodiments;

FIG. 5 provides a front view of an example server rack having a tray including integrated fans mounted at a tray position, according to certain embodiments;

FIG. 6 provides a close-up of an example liquid cooling manifold connector, in accordance with certain embodiments;

FIG. 7 provides a top view of an example artificial intelligence (AI) server mounted within the server rack, according to certain embodiments;

FIG. 8 provides a front view of an example pluggable liquid cooling connector, according to certain embodiments;

FIG. 9 provides a partial cross-sectional view of an example tray in fluid communication with a liquid cooling manifold of a server rack via a pluggable liquid cooling connector, according to certain embodiments;

FIG. 10 provides a block diagram of an example system that may include one or more datacenters including server racks according to certain embodiments;

FIG. 11 provides a schematic diagram of an example datacenter that may include one or more optical interconnects according to certain embodiments;

FIG. 12 provides a block diagram that schematically illustrates a computing system that may include one or more trays mounted in one or more server racks of various embodiments;

FIG. 13 illustrates an example computing environment, in accordance with at least one embodiment; and

FIG. 14 illustrates another example computer system that may include one or more trays mounted within one or more server racks, according to at least one embodiment.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

Various embodiments provide server racks configured for accommodating various trays having a variety of cooling requirements and configured to host at least a respective portion of one or more L1 domains in datacenters having a variety of architectures allowing the creation of a variety of sizes of L1 domains leveraging common elements between different datacenter environments. A flexible platform that can accommodate various tray designs within a rack is provided to enhance configurability and adaptability in datacenter environments and maintain thermal and power domains within different configurations. The tray structures are reconfigurable to allow for different types of trays, such as switch-based and compute-based trays, within a single rack. The infrastructure built into the rack is adaptable and supports different L1 domains, liquid cooling, and air cooling.

Conventional racks may require different trays with different cooling, power supply, and/or other requirements to be mounted within different racks. However, when trays that are assigned to the same L1 domain of the datacenter are hosted by different racks, communication latency and/or signal degradation across long distances across the datacenter may reduce the efficiency and reliability of the datacenter. Therefore, technical problems exist regarding enabling various trays with various requirements to be mounted within a common rack.

Various embodiments provide technical solutions to these technical problems. For example, various embodiments provide a server rack comprising a plurality of tray support structures that are each configured to support a tray. Each of the support structures is configured to accommodate a selected one of air cooling of a tray mounted and/or supported by the support structure or liquid cooling of a tray mounted and/or supported by the support structure. For example, the server rack may include a liquid cooling manifold comprising a plurality of pluggable liquid cooling connectors that each correspond to a respective support structure. Trays configured to be liquid cooled may be placed into fluid communication with the liquid cooling manifold via pluggable liquid cooling connectors corresponding to the respective support structures at which the trays configured to be liquid cooled are supported and/or mounted. Trays configured to be air cooled may be mounted and/or supported by any of the support structures such that integrated fans of the trays configured to be air cooled may be effectively operated. The trays configured to be air cooled may not be placed into fluid communication with the liquid cooling manifold and the liquid cooling manifold remains operational for providing liquid cooling to any trays mounted within the server rack that are configured for liquid cooling.

In various embodiments, the server rack comprises chassis and rails that are Electronic Industries Alliance (EIA) standards compliant. The chassis and/or rails define and/or comprise the support structures. As such a variety of trays may be mounted and/or supported by the support structures. In various embodiments, the server rack includes a busbar that is Open Rack Version 3 (ORV3) standards compliant, enabling powering of a variety of trays mounted within the server rack.

Thus, various embodiments provide a server rack configured for accommodating a variety of trays in various configurations. For example, trays that generate larger amounts of heat may be separated from one another within the server rack to reduce generation of hot spots within the server rack. As a result various embodiments provide a server rack that may be used to provide a highly configurable datacenter that may be optimized for efficiency and reliability. Therefore, various embodiments provide improvements to the fields of datacenters, server racks, datacenter architecture configurability, and/or the like.

### Example Server Rack

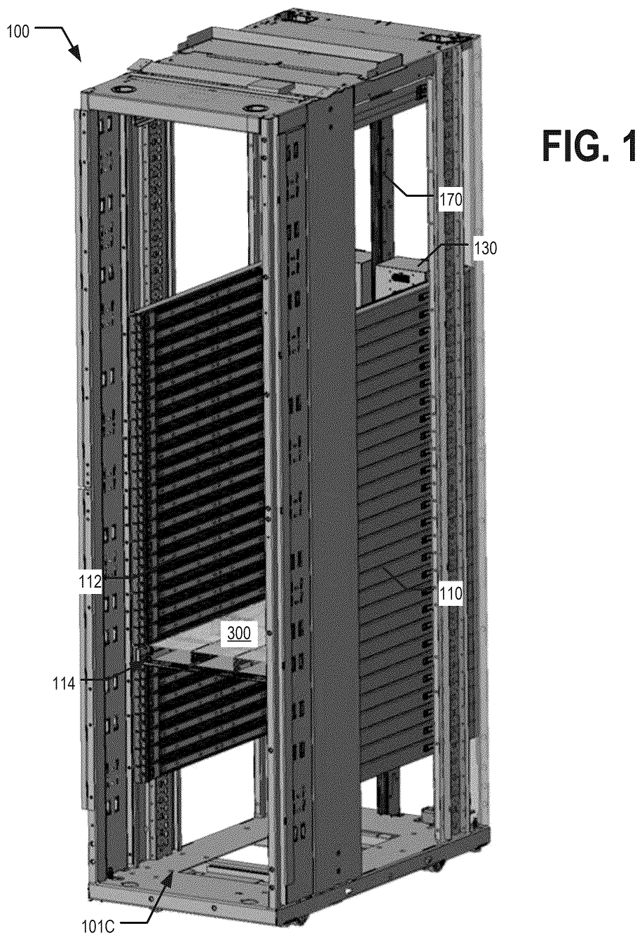

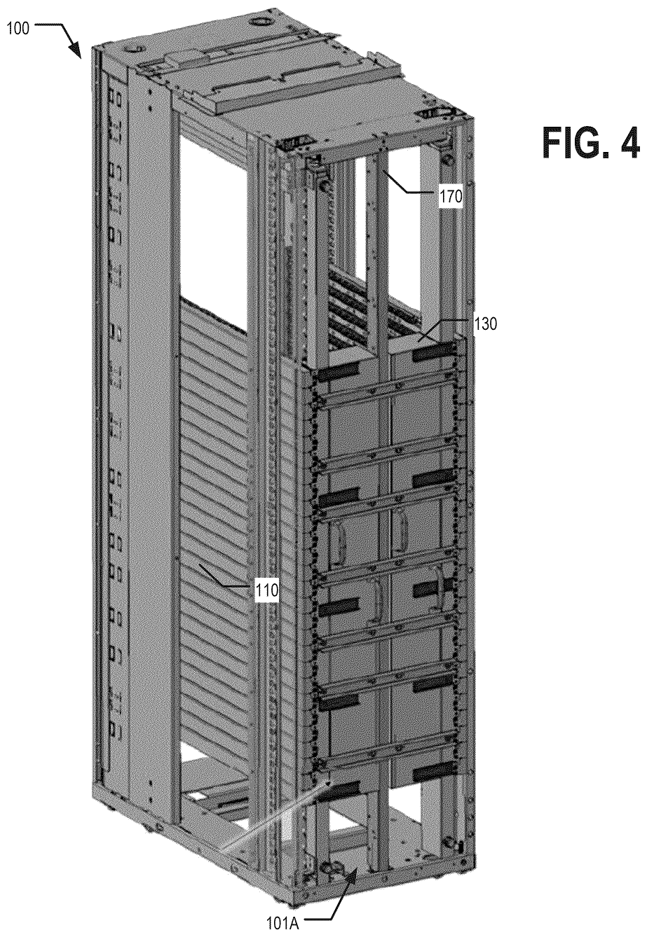

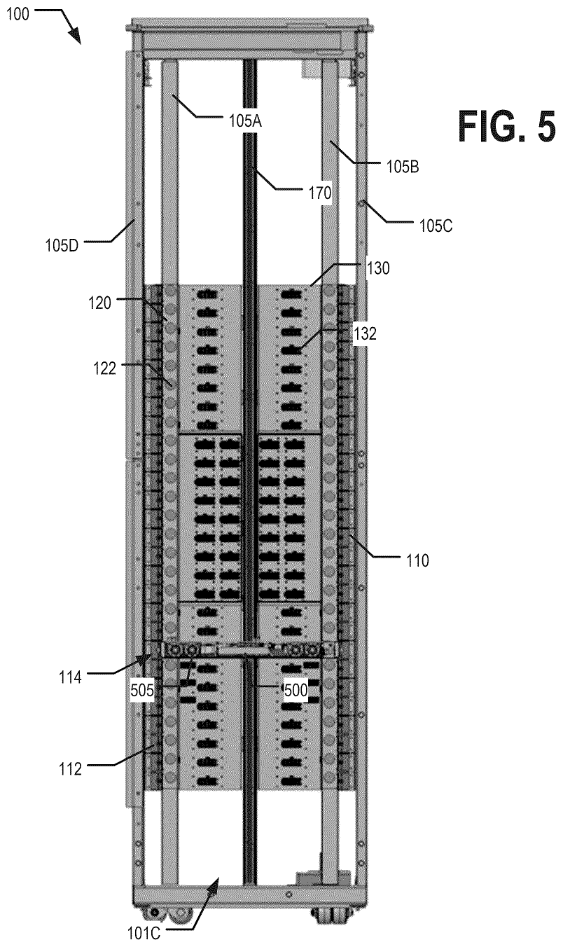

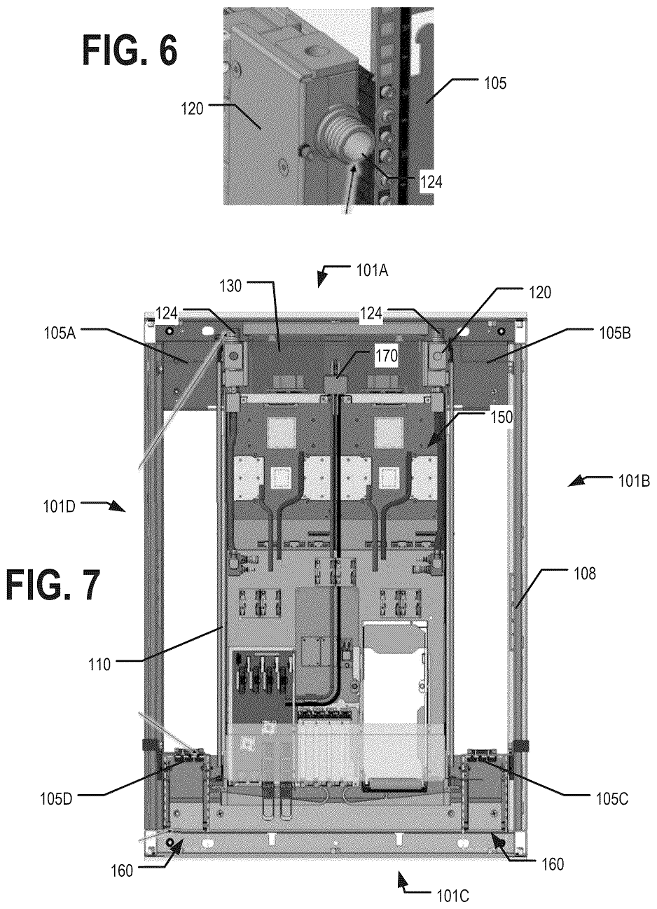

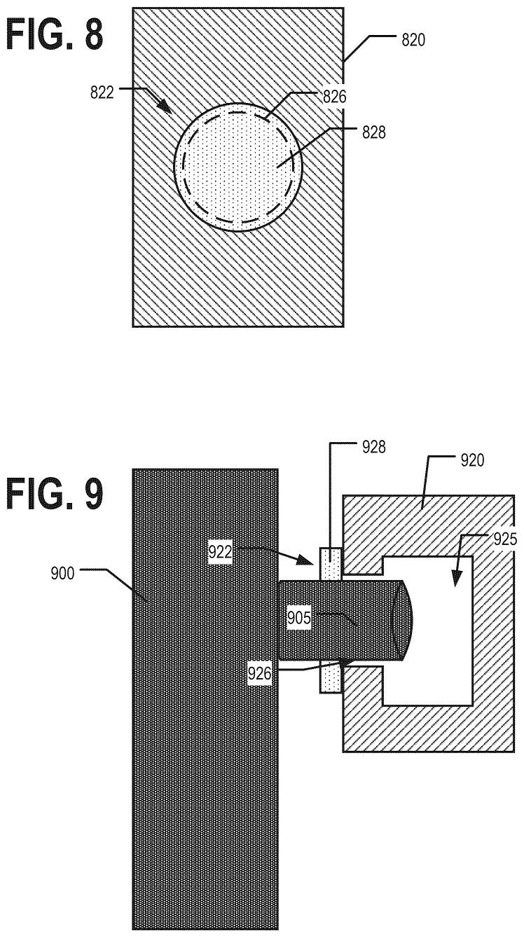

FIGS. 1-5 provide a variety of views of example server racks 100. In various embodiments, a server rack 100 comprises a plurality of tray support structures 112. The plurality of support structures 112 are each configured to support a tray 300, 500. Each support structure accommodates a selected one of air or liquid cooling of the tray supported by the support structure. In various embodiments, the server rack 100 is configured to accommodate trays configured for liquid cooling and trays configured for air cooling at any tray location. For example, each of the support structures 112 are configured to accommodate a selected one of air or liquid cooling of the tray supported by the support structure. In various embodiments, the server rack comprises one or more liquid cooling manifolds 120. For example, in the illustrated embodiments, the server rack 100 includes two liquid cooling manifolds 120 extending at least part of the way between the bottom of the server rack and the top of the server rack along the backside 101A of the server rack 100.

In various embodiments, a server rack 100 comprises a plurality of vertical structural members 106 (e.g., 106A-106D), a bottom frame 102 and a top frame 104. For example, the bottom frame 102 is disposed at the bottom of the server rack 100 and may comprise various components configured for interacting with a substrate (e.g., floor) upon which the server rack 100 is disposed (e.g., wheels, rubber feet, and/or the like). The top frame 104 is disposed at the top of the server rack 100. In some embodiments, a ventilated cover 103 is secured to the top frame 104. For example, the ventilated cover 103 may decrease dust falling onto the trays mounted within the server rack while enabling warm air to be vented out through the ventilated cover 103.

The plurality of vertical structural members 106 are each secured to the bottom frame 102 at one end and secured to the top frame 104 at an opposite end. For example, the vertical structural members 106 extend from the bottom frame 102 to the top frame 104 and define a backside 101A, a front side 101C, and two lateral sides 101B, 101D of the server rack 100.

In various embodiments, the server rack 100 comprises a busbar 170. In certain embodiments, the busbar 170 is disposed on the backside 101A of the server rack 100. For example, the busbar 170 may extend at least a portion of the way between the bottom frame 102 and the top frame 104 along the backside 101A of the server rack 100. In various embodiments, the busbar 170 is configured to provide electrical power to trays (e.g., trays 300, 500) mounted within the server rack 100. In some embodiments, the busbar 170 is configured to provide DC electrical power to trays mounted within the server rack 100. For example, the busbar 170 may be in electrical communication with power supply components housed in the top frame 104, the bottom frame 102, and/or another location within the server rack 100 such that the busbar 170 is supplied with an appropriate current or voltage differential for powering trays mounted within the server rack 100. In various embodiments, the busbar is in compliance with the ORV3 standards. In some embodiments, the busbar 170 is configured to support a higher amperage than ORV3 standards.

In various embodiments, the server rack 100 comprises a cable cartridge 130. In various embodiments, the cable cartridge 130 is mounted to the backside 101A of the server rack 100. The cable cartridge 130 extends at least a portion of the way between the bottom frame 102 and the top frame 104 of the server rack 100. The cable cartridge 130 comprises a plurality of cable connectors 132. Each cable connector 132 corresponds to a tray location 114 and is configured to mate with a corresponding cable connector disposed on a backside of a tray 300, 500 inserted into and/or mounted at the tray location 114. For example, the cable cartridge 130 comprises a plurality of electrical and/or optical cables configured to facilitate communication between trays mounted within the server rack 100 according to a desired topology and/or connectivity. In certain embodiments, the cable cartridge 130 is independent of the busbar 170. For example, the cable cartridge 130 may be removed from the server rack 100 and replaced with a different cable cartridge 130 without affecting or removing the busbar 170. In various embodiments, the cable cartridge and/or cable connectors are in compliance with EIA standards.

In various embodiments, the server rack 100 comprises a chassis 110. In various embodiments, the chassis 110 extends at least a portion of the way between the bottom frame 102 and the top frame 104 of the server rack 100 on the lateral sides 101B, 101D of the server rack 100. In various embodiments, the chassis 110 comprises a plurality of support structures 112. The plurality of support structures 112 are each configured to support a tray 300, 500. For example, the plurality of support structures 112 define a plurality of tray locations 114. Each tray location 114 is a location within the server rack 100 at which a tray may be mounted such that the tray is supported by the corresponding support structure(s) 112. In various embodiments, the chassis 110 is characterized by a one-unit pitch. Other pitches may be utilized in various embodiments. In various embodiments, the chassis 110 is compliant with EIA standards.

In various embodiments, the server rack 100 comprises a plurality of rails 105 (e.g., 105A, 105B, 105C, 105D). In various embodiments, the rails 105 are secured to the bottom frame 102 and the top frame 104 of the server rack 100. In various embodiments, the rails 105 are configured to have various components of the server rack 100 secured thereto (e.g., via mechanical fasteners). For example, the chassis 110, cable cartridge 130, liquid cooling manifold 120, cross supports 108, and/or the like may be secured to the rails 105. In various embodiments, the rails 105 are compliant with EIA standards.

In various embodiments, a mesh 140 may be disposed on at least a portion of one or more lateral sides 101B, 101D of the server rack 100.

In various embodiments, the server rack 100 comprises cable supports 160 configured to enable organization of any front-of-rack cables connected to trays 300, 500 via the front side 101C of the server rack 100.

In some embodiments, the server rack 100 is configured to receive a AI server 150 therein. FIG. 7 provides a top view of an example AI server 150. The AI server 150 may be interconnected to other servers via the cable cartridge 130. The AI server may receive electrical power via the busbar 170.

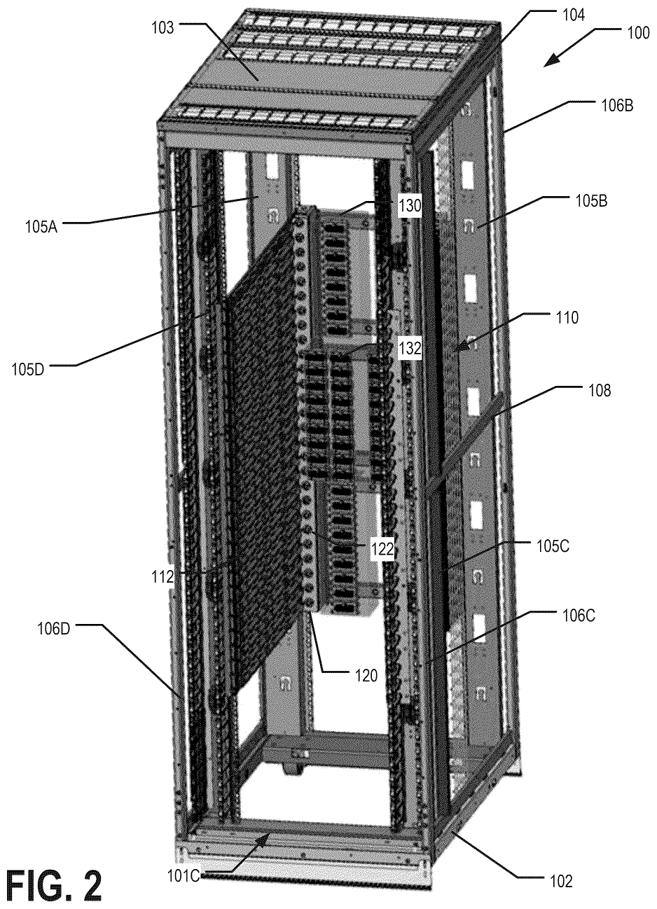

In various embodiments, each liquid cooling manifold 120 includes at least one hose coupler 124. FIG. 6 illustrates a hose coupler 124 of a liquid cooling manifold 120. As shown in FIG. 2, in some embodiments, each liquid cooling manifold 120 includes a first hose coupler 124 at the top of the liquid cooling manifold 120 and a second hose coupler 124 at the bottom of the liquid cooling manifold 120. Each hose coupler 124 is configured to have a hose or tube connected thereto. For example, the hose or tube may be configured to provide a cooled fluid (e.g., liquid nitrogen, a liquid/fluid coolant, and/or the like) for use in liquid cooling one or more trays to the liquid cooling manifold 120 and/or to remove warmed fluid from the liquid cooling manifold 120. In some embodiments, the warmed fluid is provided to a cooling unit (e.g., for interaction with a cold plate, cold finger, and/or the like) such that the fluid may then be recirculated as cooled fluid.

In various embodiments, the liquid cooling manifold 120 includes a plurality of pluggable liquid cooling connectors 122. Each pluggable liquid cooling connector 122 corresponds to a respective support structure 112 and/or tray location 114 defined by the respective support structure 112. In various embodiments, each pluggable liquid cooling connector 122 is configured to enable a tray to selectively be placed into fluid communication with the liquid cooling manifold 120 and to fluidly seal an access point to the liquid cooling manifold 120 when a tray is not selectively placed into fluid communication with the liquid cooling manifold via the pluggable liquid cooling connector.

The pluggable liquid cooling connectors 122 are configured such that, at each tray location 114, a tray may be mounted such that the tray may be fluidly coupled to the pluggable liquid cooling connector(s) 122 corresponding to that tray location or may not be fluidly coupled to the pluggable liquid cooling connector(s) 122 corresponding to that tray location without enabling fluid to leak out of the liquid cooling manifold(s) 120 and/or without substantially affecting the liquid cooling of any trays mounted within the server rack 100 that are fluidly coupled to the liquid cooling manifold(s) 120.

For example, some trays 500 may include integrated fans 505 that are configured to air cool the tray 500 and may not be fluidly coupled to the liquid cooling manifold 120. The liquid cooling manifold 120 is configured such that trays that are to be fluidly coupled to the liquid cooling manifold 120 may be mounted at any tray location within the server rack 100 and trays that are to be air cooled (e.g., via integrated fans and therefore not fluidly coupled to the liquid cooling manifold) may be mounted at any tray location within the server rack 100.

For example, as shown in FIG. 8, each pluggable liquid cooling connector 822 comprises an access point 826 configured for providing fluid communication access with the liquid cooling manifold 820. For example, a pluggable liquid cooling connector 822 may include a sealing component 828 configured to fluidly seal the access point 826 when the access point is not being used to selectively place a tray into fluid communication with the liquid cooling manifold 820. In some embodiments, the sealing component 828 is further configured to at least in part seal a fluid connection between a tray and the access point 826 while the access point 826 is being used to selectively place the tray into fluid communication with the liquid cooling manifold 820.

For example, FIG. 9 illustrates a portion of an example tray 900 that includes a fluid connector 905. For example, the fluid connector 905 may be a hollow component that extends out of the back of the tray 900 and is configured to place a liquid cooling path of the tray 900 into fluid communication with the liquid cooling manifold 920. For example, the fluid connector 905 may be inserted into the access point 926 such that the fluid connector 905 is in fluid communication with a fluid conduit 925 of the liquid cooling manifold 920. In various embodiments, the liquid cooling path of the tray 900 and/or the liquid cooling manifold 920 is configured such that cooled fluid flows from the fluid conduit 925 into the fluid connector 905. The cooled fluid extracts thermal energy from the tray as the fluid traverses the liquid cooling path of the tray and becomes warmed fluid. The warmed fluid is then returned to the fluid conduit 925 of the same or a different liquid cooling manifold 920 (e.g., fluidly coupled to the tray 900 via the same or a different fluid connector 905). The sealing component 928 is configured to at least partially seal the fluid connection between the fluid connector 905 and the access point 926 of the pluggable liquid cooling connector 922. For example, the sealing component 928 may prevent any cooled or warmed fluid from leaking out of the liquid cooling manifold 920 through the access point 926 and/or around the fluid connector 905.

In another example embodiment, each pluggable liquid cooling connector 122 may be associated with a switch or valve configured to activate or deactivate the corresponding pluggable liquid cooling connector 122. For example, when the switch or valve corresponding to a pluggable liquid cooling connector 122 is in an activated or on position, fluid (e.g., cooled fluid, liquid coolant, and/or the like) is able to flow through the pluggable liquid cooling connector 122 to enable fluid communication between the liquid cooling manifold 120 and the fluid connector of a tray mounted at the corresponding tray location. When the switch or valve corresponding to the pluggable liquid cooling connector 122 is in the deactivated or off position, fluid is not able to flow through the pluggable liquid cooling connector 122. For example, either no tray or a tray configured for air cooling (e.g., a tray that includes integrated fans) is mounted at the corresponding tray location 114.

Pluggable liquid cooling connectors 122 of various embodiments may use various techniques and/or components to facilitate selective fluid communication with the liquid cooling manifold 120 via the pluggable liquid cooling connectors 122. In some embodiments, instead of a fluid connector of a tray being inserted into the access point of a pluggable liquid cooling connector 122, the fluid connector of a tray may be configured to couple onto an outer surface of the pluggable liquid cooling connector 122 (e.g., similar to a hose coupler 124, for example).

### Example Datacenter

In various embodiments, a datacenter may include one or more server racks 100 where each server rack is configured to have one or more trays mounted therein. For example, a tray may include one or more processing units, switches, and/or other processing components. The various trays of a server rack 100 may be in communication with one another according to a topology of the datacenter via cable cartridges 130. Various server racks 100 may be in communication with one another via optical interconnects, in accordance with a topology of the datacenter. In various embodiments, at least one server rack 100 includes one more trays that are air cooled (e.g., include integrated fans) and one or more trays that are liquid cooled (e.g., are fluidly coupled to the liquid cooling manifold 120 of the server rack 100). For example, a server rack 100 may include a first L1 domain comprising one or more trays that are air cooled and a second L1 domain comprising one or more trays that are liquid cooled.

Datacenters may include multiple network switches in a particular topology, such as a fat tree topology, a slim fly topology, a dragonfly topology, and/or the like. The specifications and makeup of the network switches in the topology affects the overall network performance (e.g., bandwidth capability) of the datacenter.

Datacenters are the storage and data processing hubs of the internet. The massive deployment of cloud applications is causing datacenters to expand exponentially in size, stimulating the development of faster switches than can cope with the increasing data traffic inside the datacenter. Current state-of-the-art switches are capable of handling 12.8 Tb/s of traffic by employing electrical switches in the form of application specific integrated circuits (ASICs) equipped with 256 data lanes, each operating at 50 Gbps. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

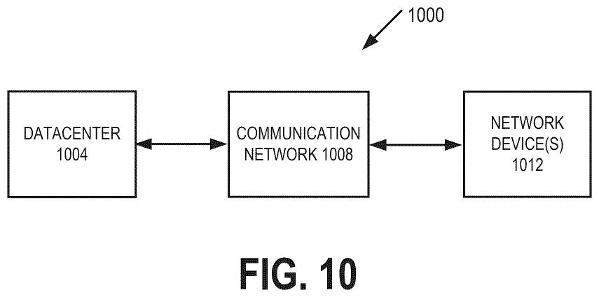

FIG. 10 illustrates a system 1000 according to at least one example embodiment. The system 1000 includes a datacenter 1004, a communication network 1008, and one or more network devices 1012. In at least one example embodiment, the datacenter 1004 corresponds to a collection of network devices, such as network switches (e.g., Ethernet switches) connected with a collection of servers or compute nodes. The datacenter 1004 may adhere to a networking topology (e.g., a hierarchal networking topology), such as a fat tree topology, a Slim Fly topology, a Dragonfly topology, and/or the like. The datacenter 1004 routes traffic amongst the network switches and servers therein, and at least one layer of the topology in the datacenter 1004 is coupled to the communication network 1008 to allow networking traffic to flow between the datacenter 1004 and the network device(s) 1012.

Examples of the communication network 1008 that may be used to connect the datacenter 1004 and the network device(s) 1012 include an Internet Protocol (IP) network, an Ethernet network, an InfiniBand (TB) network, a Fibre Channel network, the Internet, a cellular communication network, a wireless communication network, combinations thereof (e.g., Fibre Channel over Ethernet), variants thereof, and/or the like.

The one or more network devices 1012 may include switch, router, or Network Interface Controller (NIC), interconnect using ports, one or more of Personal Computer (PC), a laptop, a tablet, a smartphone, a server, a collection of servers, and/or any suitable computing device for sending and receiving signals over the communication network 1008. In at least one example embodiment, the one or more network devices 1012 correspond to another datacenter, similar to or the same as datacenter 1004.

As noted above, the datacenter 1004 and/or the network device(s) 1012 may include storage devices and/or processing circuitry for carrying out computing tasks, for example, tasks associated with controlling the flow of data internally and/or over the communication network 1008. Such processing circuitry may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory).

Additionally or alternatively, the processing circuitry may comprise hardware, such as an application specific integrated circuit (ASIC). For example, the processor may be or include one or more of an Integrated Circuit (IC) chip, a microprocessor, a Central Processing Unit (CPU), a Graphics Processing Unit (GPU), a Data Processing Unit (DPU), quantum processing units (QPUs), a plurality of parallel processing units (PPUs), a Field Programmable Gate Array (FPGA), a network interface controller (NIC), an ASIC, combinations thereof, and the like. The processing circuitry may comprise an ASIC and/or may be capable of performing as a central processing unit (CPU), a graphics processing unit (GPU), a network interface controller (NIC), a data processing unit (DPU), or any other computing device in which with data is received and/or transmitted. QPUs configured to perform one or more operations associated with a quantum algorithm In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

Some or all of the processing circuitry may be provided on a Printed Circuit Board (PCB) or collection of PCBs. It should be appreciated that any appropriate type of electrical component or collection of electrical components may be suitable for inclusion in the processing circuitry.

In addition, although not explicitly shown, it should be appreciated that the datacenter 1004 and network device(s) 1012 may include one or more communication interfaces for facilitating wired and/or wireless communication between one another and other unillustrated elements of the system 1000.

In related art systems, a fat tree topology may use the same electrical switching devices on all layers (edge, aggregation, core). For example, each switching device may be 1 U switch, where 1 U refers to the industry standard size for rack-mounted switch and/or server. The interconnection between switches of different layers may be accomplished with optical links or optical interconnects using active optical cables and optical transceivers implemented in a pluggable form factor (also referred to as “pluggables”).

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

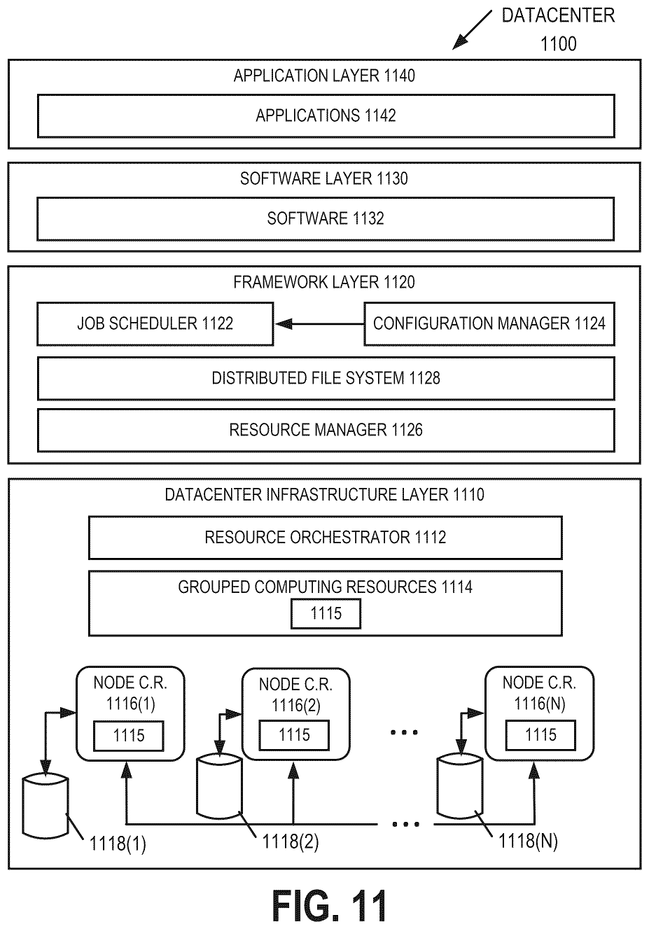

FIG. 11 illustrates an example datacenter 1100, in which at least one embodiment may be used. In at least one embodiment, datacenter 1100 includes a datacenter infrastructure layer 1111, a framework layer 1120, a software layer 1130, and an application layer 1140.

In at least one embodiment, as shown in FIG. 11, datacenter infrastructure layer 1111 may include a resource orchestrator 1112, grouped computing resources 1114, and node computing resources (“node C.R.s”) 1116(1)-1116(N), where “N” represents a positive integer (which may be a different integer “N” than used in other figures). In at least one embodiment, node C.R.s 1116(1)-1116(N) may include, but are not limited to, any number of central processing units (“CPUs”) or other processors (including accelerators, field programmable gate arrays (FPGAs), graphics processors, etc.), memory storage devices 1118(1)-1118(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R. s from among node C.R. s 1116(1)-1116(N) may be a server having one or more of above-mentioned computing resources.

In at least one embodiment, grouped computing resources 1114 may include separate groupings of node C.R. s housed within one or more racks (not shown), or many racks housed in datacenters at various geographical locations (also not shown). In at least one embodiment, separate groupings of node C.R.s within grouped computing resources 1114 may include grouped compute, network, memory, or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 1112 may configure or otherwise control one or more node C.R.s 1116(1)-1116(N) and/or grouped computing resources 1114. In at least one embodiment, resource orchestrator 1112 may include a software design infrastructure (“SDI”) management entity for datacenter 1100. In at least one embodiment, resource orchestrator 1112 may include hardware, software or some combination thereof.

In at least one embodiment, as shown in FIG. 11, framework layer 1120 includes a job scheduler 1122, a configuration manager 1124, a resource manager 1126 and a distributed file system 1128. In at least one embodiment, framework layer 1120 may include a framework to support software 1132 of software layer 1130 and/or one or more application(s) 1142 of application layer 1140. In at least one embodiment, software 1132 or application(s) 1142 may respectively include web-based service software or applications, such as those provided by Amazon Web Services, Google Cloud and Microsoft Azure. In at least one embodiment, framework layer 1120 may be, but is not limited to, a type of free and open-source software web application framework such as Apache Spark™ (hereinafter “Spark”) that may utilize distributed file system 1128 for large-scale data processing (e.g., “big data”). In at least one embodiment, job scheduler 1122 may include a Spark driver to facilitate scheduling of workloads supported by various layers of datacenter 1100. In at least one embodiment, configuration manager 1124 may be capable of configuring different layers such as software layer 1130 and framework layer 1120 including Spark and distributed file system 1128 for supporting large-scale data processing. In at least one embodiment, resource manager 1126 may be capable of managing clustered or grouped computing resources mapped to or allocated for support of distributed file system 1128 and job scheduler 1122. In at least one embodiment, clustered or grouped computing resources may include grouped computing resources 1114 at datacenter infrastructure layer 1111. In at least one embodiment, resource manager 1126 may coordinate with resource orchestrator 1112 to manage these mapped or allocated computing resources.

In at least one embodiment, software 1132 included in software layer 1130 may include software used by at least portions of node C.R.s 1116(1)-1116(N), grouped computing resources 1114, and/or distributed file system 1128 of framework layer 1120. In at least one embodiment, one or more types of software may include, but are not limited to, Internet web page search software, e-mail virus scan software, database software, and streaming video content software.

In at least one embodiment, application(s) 1142 included in application layer 1140 may include one or more types of applications used by at least portions of node C.R.s 1116(1)-1116(N), grouped computing resources 1114, and/or distributed file system 1128 of framework layer 1120. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 1124, resource manager 1126, and resource orchestrator 1112 may implement any number and type of self-modifying actions based on any amount and type of data acquired in any technically feasible fashion. In at least one embodiment, self-modifying actions may relieve a datacenter operator of datacenter 1100 from making possibly bad configuration decisions and possibly avoiding underutilized and/or poor performing portions of a datacenter.

In at least one embodiment, datacenter 1100 may include tools, services, software, or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 1100. In at least one embodiment, trained machine learning models corresponding to one or more neural networks may be used to infer or predict information using resources described above with respect to datacenter 1100 by using weight parameters calculated through one or more training techniques described herein.

In at least one embodiment, datacenter may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 1115 are used to perform inferencing and/or training operations associated with one or more embodiments. In at least one embodiment, inference and/or training logic 1115 may be used in system FIG. 11 for inferencing or predicting operations based, at least in part, on weight parameters calculated using neural network training operations, neural network functions and/or architectures, or neural network use cases described herein.

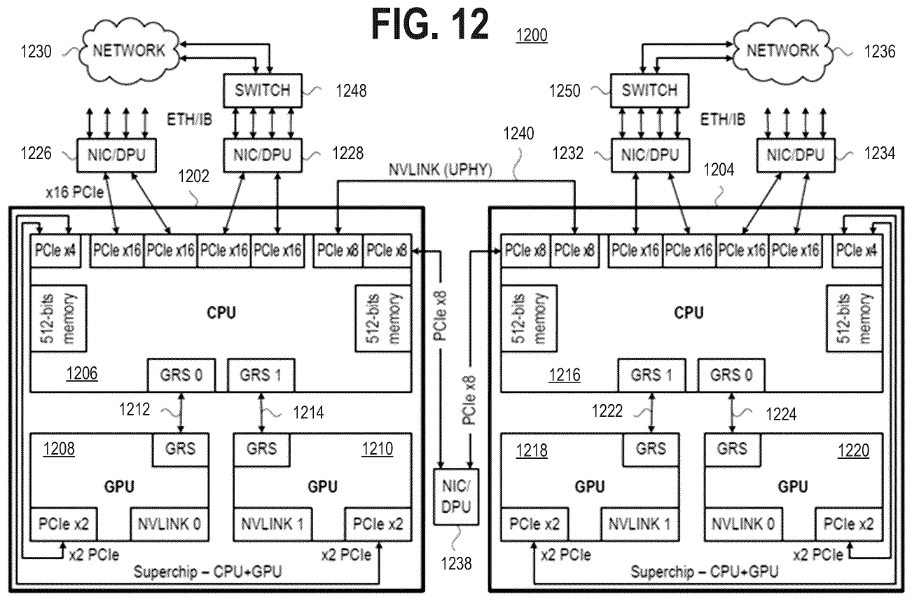

FIG. 12 is a block diagram that schematically illustrates a computing system 1200, e.g., a data center or a High-Performance Computing (HPC) cluster, in accordance with an embodiment that is described herein. System 1200 comprises a plurality of subsystems, e.g. multiple processing devices coupled to each other, multiple network devices, and multiple networks, according to at least one embodiment. Computing system 1200 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1200 and to one or more external networks 1230, 1236. In the present example, system 1200 comprises a packet switch 1248 that connects NIC/DPU 1228 to network 1230, and a packet switch 1250 that connects NIC/DPU 1232 to network 1236.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1200 can include one or more CPUs and one or more GPUs.

FIG. 12 also demonstrates an example architecture of a multi-GPU architecture. As illustrated in the figure, computing system 1200 includes a processing device 1202 with a multi-GPU architecture. In particular, processing device 1202 may be a system-on-chip and includes multiple subsystems such as a CPU 1206, a GPU 1208, and a GPU 1210. CPU 1206 can be coupled to GPU 1208 via a die-to-die (D2D) or chip-to-chip (C2C) interconnect 1212, such as a Ground-Referenced Signaling interconnect (GRS interconnect). CPU 1206 can be coupled to GPU 1210 via a D2D or C2C interconnect 1214. CPU 1206 can also couple to GPU 1208 and GPU 1210 via PCIe interconnects.

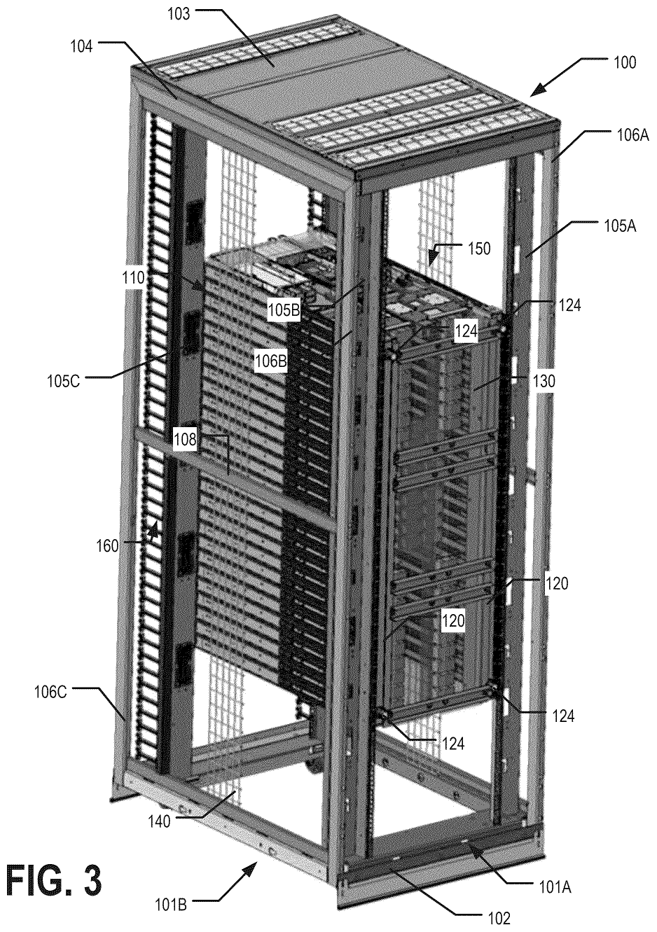

CPU 1206 can be coupled to one or more NICs or DPUs, which are coupled to one or more networks. For example, as illustrated in FIG. 3, CPU 1206 is coupled to a first NIC/DPU 1226, which is coupled to a network 1230. CPU 1206 is also coupled to a second NIC/DPU 1228, which is coupled to network 1230 via switch 1248. NIC/DPU 1226 and NIC/DPU 1228 can be coupled to network 1230 over Ethernet (ETH), NVLINK or InfiniBand (IB) connections, for example.

Computing system 1200 also includes a processing device 1204 with a multi-GPU architecture. In particular, processing device 1204 includes multiple subsystems including a CPU 1216, a GPU 1218, and a GPU 1220. CPU 1216 can be coupled to GPU 1218 via an D2D or C2C interconnect 1222. CPU 1216 can be coupled to GPU 1220 via a D2D or C2C interconnect 1224. CPU 1216 can also couple to GPU 1218 and GPU 1220 via PCIe interconnects. CPU 1216 can be coupled to one or more NICs or DPUs, which are coupled to one or more networks. For example, as illustrated in FIG. 3, CPU 1216 is coupled to a first NIC/DPU 1232, which is coupled to a network 1236. CPU 1216 is also coupled to a second NIC/DPU 1234, which is coupled to network 1236 via switch 1250. NIC/DPU 1232 and NIC/DPU 1234 can be coupled to network 1236 over Ethernet (ETH), NVLINK or InfiniBand (IB) connections.

In at least one embodiment, processing device 1202 and processing device 1204 can communication with each other via a NIC/DPU 1238, such as over PCIe interconnects. Processing device 1202 and processing device 1204 can also communicate with each other over a high-bandwidth communication interconnects 1240, such as an NVLink interconnect or other high-speed interconnects. The packet switches in FIG. 3 may comprise, for example, Nvidia Quantum-2 switches. The NICs/DPUs in the figure may comprise, for example, Nvidia Bluefield DPUs.

In various embodiments, one or more of the interconnects 1212, 1214, 1222, 1224 may be optical interconnects disclosed herein. Additionally, in various embodiments, switches 1248, 1250 may be in communication with NIC/DPU 1228, 1232, respectively, via one or more optical interconnects disclosed herein. In some embodiments, NIC/DPU 1226, 1234 may be in communication with one or more additional elements via optical interconnects disclosed herein. For example, various elements of the computing system 1200 may be in communication with one another via one or more optical interconnects disclosed herein.

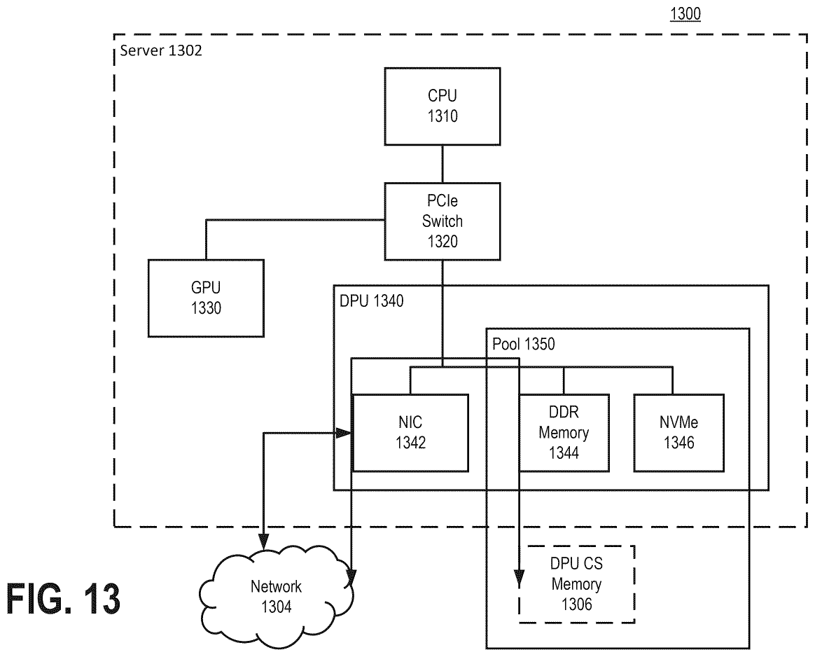

FIG. 13 illustrates an example computing environment 1300 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 1300 may include a server 1302 which may be used to perform high performance computing (HPC) workloads, such as AI training or machine learning model training. In an embodiment, the server 1302 may be an application instance or a compute node. The server 1302 may include a CPU 1310 associated with a switch 1320, such as a peripheral component interconnect express (PCIe) switch, which may control at least some data transmission over communication paths interconnecting various components. In an embodiment, the CPU 1310 may include a root complex processor.

The PCIe switch 1320 may also be associated with a GPU 1330 and a DPU 1340, and may transmit data between at least some of the CPU 1310, the GPU 1330, the DPU 1340, and other components (e.g., via one or more optical interconnects disclosed herein). In an embodiment, the PCIe switch 1320 may be associated with more than one GPU or more than one DPU. In another embodiment, the PCIe switch 1320 may be located within the DPU 1340. The PCIe switch 1320 may manage the transfer of at least some data between the CPU 1310, the GPU 1330, and the DPU 1340. In another embodiment, the number of GPUs associated with the PCIe switch 1320 may be equal to the number of DPUs associated with the PCIe switch 1320. In at least one embodiment, the server 1302 may include, without limitation, any number of the CPUs 1310, the PCIe switches 1320, the GPUs 1330, and/or the DPUs 1340, in any combination. For example, in at least one embodiment, server 1302 could include eight, sixteen, thirty-two, and/or more GPUs 1330. In at least one embodiment, communication paths interconnecting various components, including but not limited to the CPU 1310, the PCIe switch 1320, the GPU 1330, and the DPU 1340, in FIG. 13 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 1340 may include a network interface controller (NIC) 1342, a DDR memory 1344, and a non-volatile memory express (NVMe) device 1346. The NIC 1342 may be able to interface with a network 1304, which may also interface with additional NVMe devices available to the DPU 1340, such as over fabric. In an embodiment, the DPU 1340 may not include the NVMe device 1346. In another embodiment, the NVMe device 1346 may be located on the server 1302 and not on the DPU 1340. In yet another embodiment, the computing environment 1300 may include more than one of the NVMe device 1346, such as a first NVMe device in the DPU 1340 and a second first NVMe device on the server 1302 an associated directly with the PCIe switch 1320. In an embodiment, the DPU 1340 may not include the DDR memory 1344 and may include a computational storage services (CSS) in place of, or in addition to, the DDR memory 1344. For example, computing environment 1300 may include DPU computational storage (CS) memory 1306 available to the DPU 1340 as part of the CSS. The network 1304 may be able to interface with the DPU CS memory 1306 through the NIC 1342, according to any suitable interface protocol, such as remote direct memory access (RDMA) over Ethernet, InfiniBand, Fiber Channel, etc.

The total memory of the computing environment 1300 available for data storage may be expanded through the use of the DPU 1340 on nodes of the system. The DPU 1340 may have access to a pool 1350 of memory already available to the server 1302, such as double data rate (DDR) memory, on-board NVMe devices, NVMe devices over fabric, and CS. The pool 1350 of memory may include at least one of the DDR memory 1344, NVMe 1346, and the DPU CS memory 1306. The DPU 1340 may also be able to access the available memory of other DPUs as part of the pool 1350, and other DPUs may be able to access the available memory of DPU 1340, such as the pool 1350. This available memory can be accessed and utilized for data storage, without the addition of compute resources, such as compute nodes, which would be required using other solutions. The available pool 1350 accessible to the DPU 1340 may be provisioned for the server 1302 to expand the total memory available for data storage, such as to reduce the data storage load on the CPU 1310 or the GPU 1330, which can instead increase the utilization of their memory for processing. For example, during training of an AI, the model states, residual states, activation functions, and checkpoints can be stored, or offloaded, on the pool 1350 accessible to the DPU 1340.

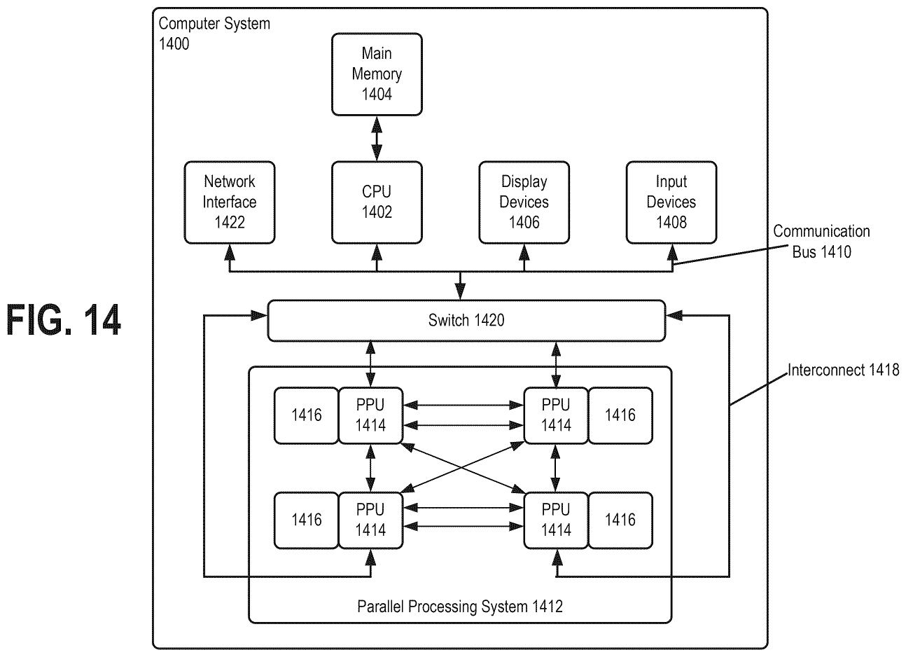

FIG. 14 illustrates a computer system 1400, according to at least one embodiment. In at least one embodiment, computer system 1400 comprises at least one optical interconnect of an example embodiment.

In at least one embodiment, computer system 1400 comprises, without limitation, at least one central processing unit (“CPU”) 1402 that is connected to a communication bus 1410 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1400 includes, without limitation, a main memory 1404 and control logic (e.g., implemented as hardware, software, or a combination thereof) and data are stored in main memory 1404 which may take form of random access memory (“RAM”). In at least one embodiment, a network interface subsystem (“network interface”) 1422 provides an interface to other computing devices and networks for receiving data from and transmitting data to other systems from computer system 1400.

In at least one embodiment, computer system 1400, in at least one embodiment, includes, without limitation, input devices 1408, parallel processing system 1412, and display devices 1406 which can be implemented using a conventional cathode ray tube (“CRT”), liquid crystal display (“LCD”), light emitting diode (“LED”), plasma display, or other suitable display technologies. In at least one embodiment, user input is received from input devices 1408 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 1404 and/or secondary storage. Computer programs, if executed by one or more processors, enable system 1400 to perform various functions in accordance with at least one embodiment. memory 1404, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 1402; parallel processing system 1412; an integrated circuit capable of at least a portion of capabilities of both CPU 1402; parallel processing system 1412; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 1400 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1412 includes, without limitation, a plurality of parallel processing units (“PPUs”) 1414 and associated memories 1416. In at least one embodiment, PPUs 1414 are connected to a host processor or other peripheral devices via an interconnect 1418 and a switch 1420 or multiplexer. In at least one embodiment, parallel processing system 1412 distributes computational tasks across PPUs 1414 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 1414, although such shared memory may incur performance penalties relative to use of local memory and registers resident to a PPU 1414. In at least one embodiment, operation of PPUs 1414 is synchronized through use of a command such as_syncthreads(), wherein all threads in a block (e.g., executed across multiple PPUs 1414) to reach a certain point of execution of code before proceeding.

The PPUs 1414 may be in communication with one another and/or switch 1420 via one or more optical interconnects in accordance with example embodiments disclosed herein.

### Conclusion

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation. That which is claimed:

1. A server rack comprising:
a plurality of tray support structures each configured to support a tray, wherein each support structure accommodates a selected one of air or liquid cooling of the tray supported by the support structure.

2. The server rack of claim 1, further comprising:
chassis and rails that are Electronic Industries Alliance (EIA) standards compliant, wherein the chassis comprises the plurality of tray support structures; and
a busbar that is Open Rack Version 3 (ORV3) standards compliant.

3. The server rack of claim 1, further comprising a liquid cooling manifold comprising a plurality of pluggable liquid cooling connectors that each correspond to a respective support structure.

4. The server rack of claim 3, wherein each pluggable liquid cooling connector of the plurality of liquid cooling connectors is configured to enable a tray to selectively be placed into fluid communication with the liquid cooling manifold and to fluidly seal an access point to the liquid cooling manifold when a tray is not selectively placed into fluid communication with the liquid cooling manifold via the pluggable liquid cooling connector.

5. The server rack of claim 4, wherein each pluggable liquid cooling connector of the plurality of liquid cooling connectors comprises an access point configured for providing fluid communication access with the liquid cooling manifold.

6. The server rack of claim 5, wherein each pluggable liquid cooling connector of the plurality of liquid cooling connectors comprises a sealing component configured to fluidly seal the access point when the access point is not being used to selectively place a tray into fluid communication with the liquid cooling manifold.

7. The server rack of claim 6, wherein the sealing component is further configured to at least in part seal a fluid connection between the tray and the access point when the access point is being used to selectively place a tray into fluid communication with the liquid cooling manifold.

8. The server rack of claim 1, wherein the server rack is configured to accommodate trays comprising tray integrated fans.

9. The server rack of claim 1, further comprising a cable cartridge comprising a plurality of cable connectors that each correspond to a respective support structure.

10. The server rack of claim 9, wherein the cable cartridge is configured to define one or more L1 domains within the server rack.

11. A server rack comprising:
a plurality of vertical structural members extending from a bottom of the server rack to a top of the server rack and defining a front side, a back side, and two lateral sides of the server rack;
a busbar disposed on the back side of the server rack and extending at least part way between the top of the server rack and the bottom of the server rack;
a liquid cooling manifold extending at least part way between the top of the server rack and the bottom of the server rack and comprising pluggable liquid cooling connectors disposed at a plurality of tray locations; and
a cable cartridge mounted on the back side of the server rack and comprising cable connectors at disposed at the plurality of tray locations,
wherein the server rack is configured to receive respective trays at respective tray locations of the plurality of tray locations such that the respective trays receive electrical power via the busbar, optionally received liquid coolant via the liquid cooling manifold, and interconnectivity between the respective trays is controlled via the cable cartridge.

12. The server rack of claim 11, further comprising a chassis comprising a plurality of tray support structures that are configured to define the plurality of tray locations.

13. The server rack of claim 12, wherein the server rack further rails that are Electronic Industries Alliance (EIA) standards compliant, the chassis is EIA compliant, and the busbar is Open Rack Version 3 (ORV3) standards compliant.

14. The server rack of claim 11, wherein each pluggable liquid cooling connector of the plurality of liquid cooling connectors is configured to enable a tray to selectively be placed into fluid communication with the liquid cooling manifold and to fluidly seal an access point to the liquid cooling manifold when a tray is not selectively placed into fluid communication with the liquid cooling manifold via the pluggable liquid cooling connector.

15. The server rack of claim 14, wherein each pluggable liquid cooling connector of the plurality of liquid cooling connectors comprises an access point configured for providing fluid communication access with the liquid cooling manifold.

16. The server rack of claim 15, wherein each pluggable liquid cooling connector of the plurality of liquid cooling connectors comprises a sealing component configured to fluidly seal the access point when the access point is not being used to selectively place a tray into fluid communication with the liquid cooling manifold.

17. The server rack of claim 16, wherein the sealing component is further configured to at least in part seal a fluid connection between the tray and the access point when the access point is being used to selectively place a tray into fluid communication with the liquid cooling manifold.

18. The server rack of claim 11, wherein the server rack is configured to accommodate trays comprising tray integrated fans.

19. The server rack of claim 11, wherein the cable cartridge is configured to define one or more L1 domains within the server rack.

20. The server rack of claim 11, wherein the cable cartridge is configured to define a topology of at least a portion of a computing network housed by the server rack.
